(19) United States
(12) Patent Application Publication
(10) Pub. No.: US 2003/0174877 A1
(43) Pub. Date: Sep. 18, 2003

(54) Method for inspecting patterns

(75) Inventor: Dror Aiger, Zoran (IL)

Correspondence Address: SUGHRUE MION, PLLC, 2100 Pennsylvania Avenue, NW, Washington, DC, 20037-3213, US

(73) Assignee: ORBOTECH LTD

(21) Appl. No.: 10/331,556

(22) Filed: Dec. 31, 2002

Related U.S. Application Data
(60) Provisional application No. 60/343,221, filed on Dec. 31, 2001.

(51) Int. Cl. G06K 9/00

(52) U.S. Cl. 382/145

(57) ABSTRACT

A method for the inspection of electrical circuit patterns including carrying out an initial inspection of a sequentially acquired image of an electrical circuit pattern to determine potential defects in the electrical circuit pattern; upon identifying a potential defect in the electrical circuit pattern in the course of the initial inspection, interrupting the initial inspection and carrying out a secondary evaluation of a portion of the sequentially acquired image including the potential defect; and following completion of the secondary inspection, resuming the initial inspection.

### CROSS REFERENCE TO RELATED APPLICATION

This application claims the benefit of U.S. Provisional Patent Application No. 60/343,221, filed Dec. 31, 2001, the disclosure of which is incorporated by reference in its entirety.

### FIELD OF THE INVENTION

The present invention relates to methods and systems for pattern inspection which are particularly useful in the inspection of electrical circuits during their fabrication.

### BACKGROUND OF THE INVENTION

The fabrication of electrical circuits, such as printed circuit boards, typically includes one or more stages during which a pattern of conductors is deposited on one or more substrate layers to be formed into a printed circuit board. At least some of the substrate layers are subjected to automated optical inspection (AOI) using, for example, V-300™, Inspire 9060™, SK-75™ or ICP 8060™ AOI systems available from Orbotech Ltd. of Yavne, Israel.

A variety of methods are employed in AOI to optically inspect electrical circuit patterns for defects. Some methods include a bit by bit comparison of an image of electrical circuit to be inspected to a reference image. Other methods include analysis of an electrical circuit to be inspected to identify the types and locations of various elements forming an electrical circuit, to determine whether all of the elements are present and properly located, and to measure various characteristics, such as the width of conductors and space between conductors, and determine whether these meet a predetermined design specification.

### SUMMARY OF THE INVENTION

The present invention seeks to provide pattern inspection systems and methods that facilitate the use of software operable on multipurpose hardware to inspect patterns in general, and to inspect electrical circuit patterns in particular.

A general aspect of the present invention relates to a pattern inspection system that is operative, using a first algorithm set, to evaluate a stream of incoming image data by comparing selected portions of incoming data to a reference and quickly filtering out portions of the incoming data which are closely similar to the reference. When the system encounters a portion of the incoming data that is not closely similar to the reference, evaluation of the incoming data is interrupted in order to further evaluate such a portion of the incoming data that is not closely similar to the reference, using a second algorithm set. The stream of incoming image data, which continues to be acquired, is temporarily stored in memory while the further evaluation is performed. Upon completion of further evaluating the portion that is not closely similar to the reference using the second algorithm set, the system returns to evaluating the stream of incoming data using the first algorithm set, first evaluating the backlog of portions which collected in memory, until encountering another portion of the incoming data that is not closely similar to the reference.

In accordance with an embodiment of the invention, the second algorithm set is more resource intensive than the first algorithm set. Preferably, the second algorithm set is better able than the first algorithm set to determine whether a portion that is not closely similar to the reference is nevertheless still sufficiently similar so that it should not be considered defective.

In accordance with an embodiment of the invention, the first algorithm set employs a global registration procedure to globally register an image of a pattern to be inspected to a reference, and then compares a first set of attributes, such as the configuration and location of a contour, in the image to corresponding attributes in the reference. Subsequently, the second algorithm set micro registers each portion of incoming data that is not closely similar to the reference so that it is in precise registration with a corresponding portion in the reference. Following micro-registration the system once again compares the first set of attributes in the portion to corresponding attributes in the reference.

Alternatively, in accordance with an embodiment of the invention, the first algorithm set evaluates a first set of attributes or characteristics, for example the location of a contour, while the second algorithm set evaluates a second set of attributes or characteristics which is larger, and/or more which requires greater computing resources than the first set, for example one or more statistical moments representing the contour.

Another general aspect of the invention relates to a system for comparing an image of a pattern to be inspected to a reference, in which it is known that the image of the pattern to be inspected should be similar to the reference and that some dissimilarities between the image and the reference indicate defects in the pattern. A generally continuous stream of image portions is provided to a processor. Portions of the image which upon comparison of a first characteristic are found to be very closely similar to the reference image, namely meet or exceed a high quality threshold, are not further considered. However, portions of the image of the pattern being inspected that fail to meet the high quality threshold are then evaluated further using a different evaluation method. The different evaluation method may employ a further step of precision alignment between the image and the reference, or may consider additional and/or different characteristics present in portions being evaluated.

In accordance with some embodiments of the invention, the further evaluation is generally performed promptly after a portion of the image is found not to meet the high quality threshold, and before all of the portions of the image are compared to the reference and evaluated using the high quality threshold. Additionally, in accordance with some embodiments of the invention, the further evaluation is performed by the same processor which is employed to compare the image to the reference and evaluate the compared portions using the high quality threshold.

Additional general aspects of the invention relate to methods for inspecting electrical circuits employing the system described above, and methods for fabricating electrical circuits including forming conductive members on an electrical circuit substrate in a predetermined pattern, optically inspecting the patterns using systems and methods described herein, and then discarding or fixing substrates which are found to be defective.

### BRIEF DESCRIPTION OF THE DRAWINGS

The present invention will be understood and appreciated more fully from the following detailed description, taken in conjunction with the drawings in which:

FIG. 1 is a simplified pictorial illustration of a pattern inspection system constructed and operative in accordance with an embodiment of the invention;

FIG. 2 is a simplified flow diagram of the functionality of the system of FIG. 1 in accordance with an embodiment of the invention;

FIG. 3 is a flow diagram of the initial inspection functionality of FIG. 1 in accordance with an embodiment of the invention;

FIGS. 4A-4F are simplified pictorial illustrations of the results of the steps in the inspection functionality of FIG. 3 in accordance with an embodiment of the invention;

FIG. 5 is a simplified flow diagram of a process for micro-registering acquired image portions and corresponding reference portions employed in embodiments of the invention;

FIGS. 6A and 6B are schematic diagrams illustrating selected aspects of the micro-registration process of the process of FIG. 5;

FIG. 7 is a simplified flow diagram of a process for performing an evaluation of suspected defects in accordance with an embodiment of the invention;

FIGS. 8A-10B are simplified pictorial illustrations of an evaluation process as applied to pairs of excessively different segments in accordance with an embodiment of the invention;

FIG. 11 is a simplified flow diagram of a preferred methodology for performing an evaluation step in the process of FIG. 7;

FIGS. 12A and 12B are simplified pictorial illustrations of contour and reference segments along with abstract representations thereof in accordance with embodiments of the invention;

FIG. 13 is a simplified pictorial illustration of the superimposition of the abstract representations of FIGS. 12A and 12B;

FIGS. 14A-14E are simplified pictorial illustrations of the computation of an abstract representation of a segment in accordance with an embodiment of the invention;

FIGS. 15A is simplified pictorial illustrations of a digital image of an electrical circuit pattern portion;

FIG. 15B is a pixelized contour representation of the digital image of FIG. 15A; and

FIG. 16 is a simplified is a simplified pictorial illustration of a digital image of a pattern defined by sub-pixel resolution contour elements.

### DETAILED DESCRIPTION OF PREFERRED EMBODIMENTS

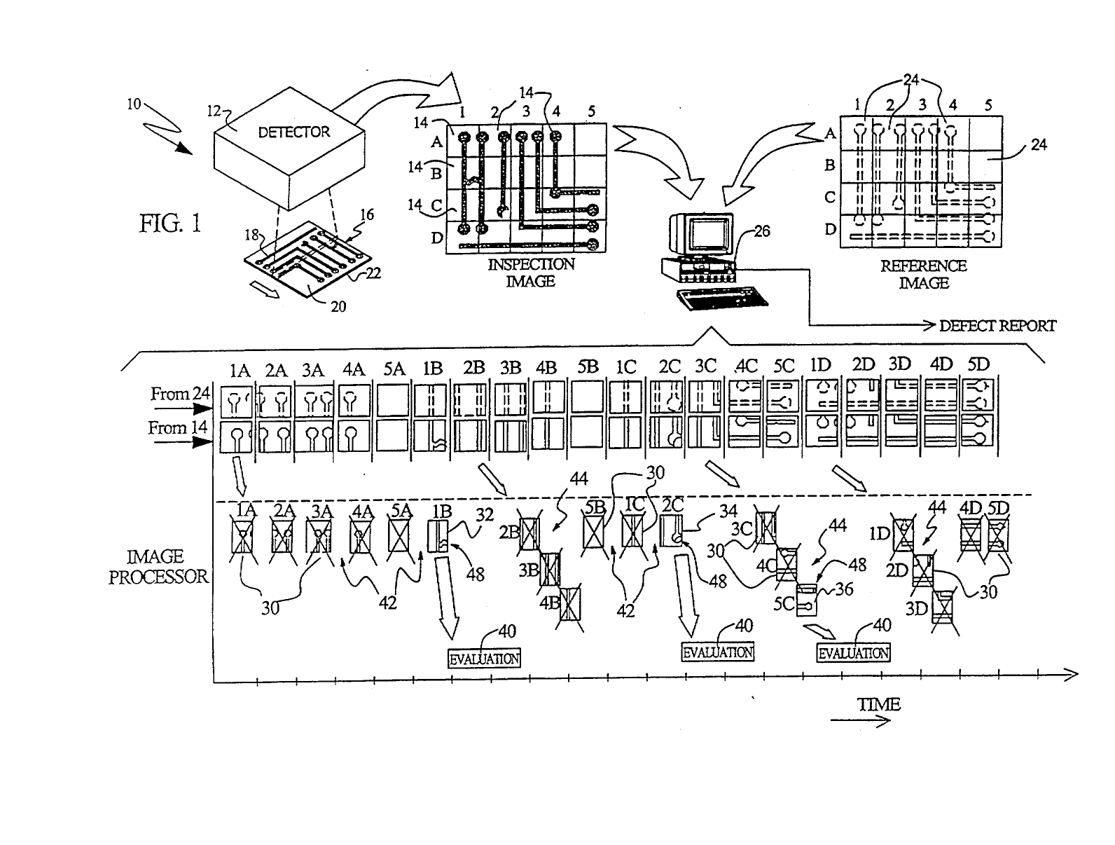

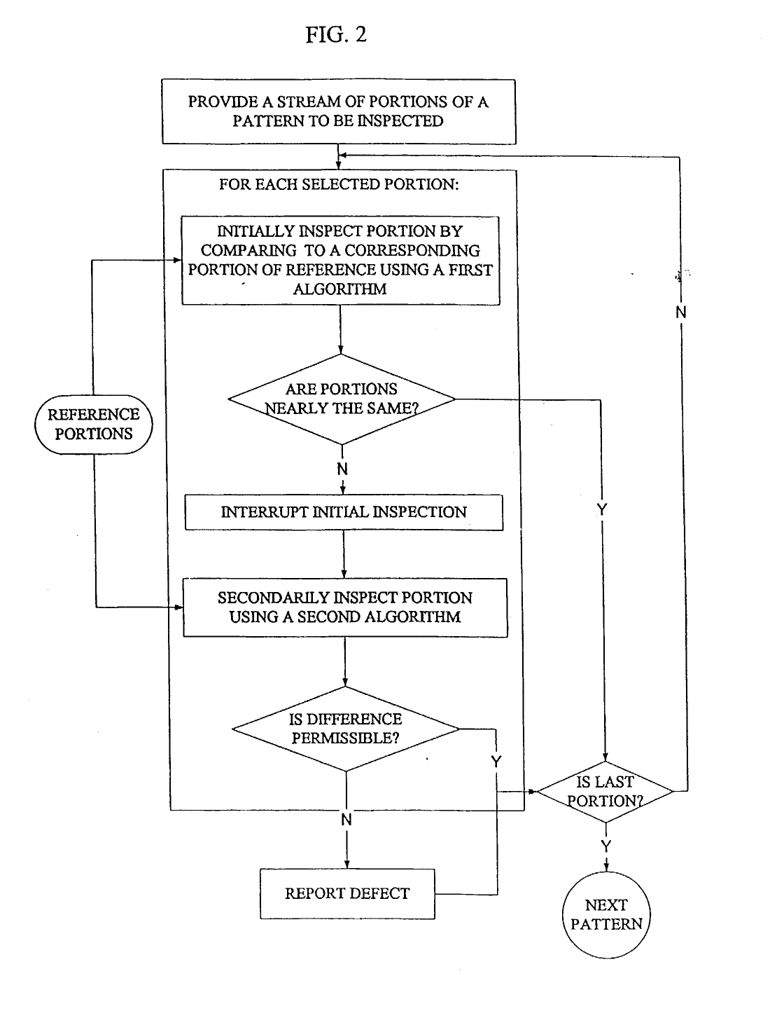

Reference is now made to FIGS. 1 and 2 which illustrate the structure and operation of a pattern inspection system 10 configured and arranged in accordance with a preferred embodiment of the invention. System 10 includes a detector assembly 12 which preferably is part of a scanner and operative to sequentially acquire a sequence of image portions 14 of a pattern being inspected 16. Pattern 16 includes, for example, a pattern of conductive members 18 formed on a surface 20 of an in-fabrication electrical circuit substrate 22. Detector assembly 12 may be operative as a line scanner to sequentially acquire image portions 14 line by line, or alternatively as an area imager operative to sequentially acquire image portions each corresponding to two-dimensional regions of the pattern 16.

As used herein, the term “electrical circuit” means any suitable electrical circuit, including without limitation, a printed circuit board, display screen, integrated circuit, multi-chip module, ball grid array substrate, interconnect device connecting between printed circuit boards and electronic components, or any other completely or partially formed electrical or electronic circuit. It is appreciated that while the following invention is described hereinbelow in the context of printed circuit boards, it is suitable for use in the inspection or detection of any suitable electrical circuit, object or pattern.

The sequence of image portions 14 is provided by detector 12 to an image processor unit 26 which preferably includes an image portion comparison functionality and a defect decision functionality. Image processor unit 26 also receives reference image portions 24, which may be derived from the output of a conventional CAM device (not shown). Image processor unit 26 is preferably an off the shelf processor, such as a SPARC (R) processor, commercially available from Sun Microsystems. The functionality of image processor unit 26 will now be described.

It is a feature of the present invention that the image portion comparison functionality is operative to initially inspect a multiplicity of locations on pattern 16, in order to locate a first plurality of locations, among the multiplicity of locations, which have a first possibility of defects. Such initial inspection is performed, for example, by a first algorithm set on a plurality of locations along a contour representing a transition between different regions of a pattern, for example a transition between conductor and substrate portions. The inventors have found that in the inspection of electrical circuits, contour representations of electrical circuit images are particularly suitable for defect inspection inasmuch as they contain sufficient information to indicate the geometrical shape and location of components defining electrical circuits. This information is in a readily processable form and is substantially more compact than the information contained in corresponding complete bit map images.

It is appreciated that typically an inspection image of a given circuit board may include plural image portions 14, as illustrated in FIG. 1. It is also appreciated that the multiplicity of locations typically includes many locations within each image portion 14. It is additionally appreciated that the present invention is preferably operative to inspect a multiplicity of electrical circuit patterns 16. In the illustrated embodiment of FIG. 1, each of the multiplicity of locations corresponds to a single image portion 14, although clearly this need not be the case.

A suitable first algorithm, or first set of algorithms, in accordance with an embodiment of the invention, includes a comparison algorithm which is operative to compare an image portion 14 to a corresponding reference image portion 24, and to discard from further consideration those image portions 14 and corresponding reference image portions 24 which are at least nearly identical, as measured, for example, by a high quality threshold. The at least nearly identical image and reference portions 14 and 24 respectively are illustrated in overlay and designated by reference numeral 30.

As seen in FIG. 1, image portions 14, preferably are each a representation of contours which correspond to the location of a transition between conductive members 18 and surface 20 of substrate 22. It is seen that several image portions 14 and their corresponding reference image portions 24, are not at least nearly identical. Each such image portion 14 exhibits at least a portion of a contour which is different from, that is to say does not generally overlap, a corresponding portion of a contour in a corresponding reference image portion 24. In FIG. 1, three such pairs of non-identical corresponding image portions and reference portions are illustrated in overlay and designated by respective reference numerals 32, 34 and 36. It is appreciated that although system 10 is described in the preferred context of inspecting a representation of contours representing a pattern, any other suitable representation of a pattern, for example a bit map, may be employed. Representations of contours are employed in a preferred embodiment of the invention inasmuch as contours constitute suitable descriptors of pattern 16 which readily facilitate determination of the presence of defects, such as nicks, protrusions, opens and short circuits, that are typical of electrical circuits.

It is a particular feature of the present invention that while performing the step of initially comparing image portions 14 to corresponding reference portions 24, upon identifying a pair of not at least nearly identical image and reference portions, such as pair 32, the initial comparison is interrupted and a second stage evaluation, designated reference numeral 40, is performed thereon. An object of evaluation 40 is to determine which of the first plurality of locations constitutes a second, smaller plurality of locations having a second possibility of defects, greater than the first possibility of defects. Clearly, in reality, the second plurality of locations may include zero, one or a greater number of locations having a second possibility of defects. Evaluation 40 preferably employs a second set of algorithms which is different from the first set of algorithms, and typically is considerably more precise and/or more robust than the first set of algorithms, such that it is able to determine which locations among the first plurality of locations is more likely to actually correspond to a defect. Typically, the second set of algorithms typically requires more computer resources resource and/or is more time consuming than the first set of algorithms. It is appreciated that while the use of only two algorithms are shown in FIG. 1, additional stages of processing, each using a successively more precise and/or more robust algorithm and/or more resource intensive algorithm, may be employed.

Particular attention is directed to the timing of acquisition of a sequence of image portions 14, the initial comparison thereof with corresponding reference portions 24 and the second stage evaluations 40. It is seen that preferably the initial comparison of each image portion takes less time than does the acquisition thereof, as indicated by the time gaps designated by reference numeral 42. It is also seen that upon initiation of a second stage evaluation 40, the initial comparison of image portions 14 is temporarily interrupted while acquisition thereof continues at the same pace as before. Upon completion of a second stage evaluation, the accumulated backlog of acquired image portions 14 undergoes initial comparison at the same speed as before but at a faster rate, since the time gaps 42 are eliminated, as shown generally by arrow 44. Once the backlog is eliminated, the rate of initial comparison returns to the original rate, including time gaps 42. It is appreciated that the above-described timing may apply equally to any other suitable embodiment wherein a multiplicity of electrical circuit patterns, which may correspond to the locations, the image portions or to the circuit boards undergo initial comparison and, as appropriate second stage evaluation.

Thus, as seen in FIG. 1, and further appreciated from FIG. 2, image portions 14 representing a multiplicity of locations may be acquired in continuum and may be provided to image processor unit 26 in a stream-like manner. The first algorithm set is operative preferably to quickly discard image portions 14 which are highly similar to corresponding reference image portions 24. Only when a pair of non-identical corresponding image and reference portions, such as pairs 32, 34 and 36, is encountered does an image portion comparison circuit employ the second algorithm set to perform a further evaluation 40 on the localized region at which the corresponding image and reference portions are not nearly identical. While operation of processor unit 26 is interrupted from comparing acquired image portions 14 to reference image portions 24 in order to perform the second algorithm set, the stream of image portions 14 continues to be acquired by detector 12 and is stored, such as in a buffer (not shown) thereby forming a temporary backlog 44 of to-be-initially compared image portions.

It is appreciated that the aforementioned inspection sequence is facilitated, in accordance with an embodiment of the invention, by the first algorithm set being relatively fast, compared to the algorithm employed in evaluation 40. Despite its speed, the first algorithm set is effective in filtering out from further evaluation a large quantity of non-defective parts of the pattern 16. In the examples shown above, the non-defective parts of pattern 16 are those parts which are both similar to and located at nearly the same location as pattern parts in a corresponding reference. Thus, in the example described hereinabove, the first algorithm set operates on the pattern 16 at a rate which is at least the same order of magnitude or faster than the rate at which an image of the pattern is acquired. Moreover, in accordance with an embodiment of the invention, the first algorithm set is operative to compare the similarity of the pattern 16 to the reference based on a first simplified set of criteria which can be quickly applied to ascertain whether the similarity meets or exceeds a very high quality threshold. This ensures that all, or nearly all, actual defects are identified. However, a possible shortcoming of the first algorithm set is that it is likely to produce a relative large quantity of false positive defects. That is to say that it falsely indicates as possibly defective a relatively large quantity of image portions which, when further evaluated, may be found to be not defective, notwithstanding the fact that they exhibit some dissimilarity when compared to a corresponding reference.

In accordance with an embodiment of the invention, the second algorithm set employed in evaluation 40 typically requires a greater amount of time and/or processing resources than the first algorithm set employed to compare image portions 14 to corresponding reference portions 24. In accordance with some embodiment of the invention, the second set of algorithms employed in evaluation 40 merely registers image portions 14 in a highly precise manner relative to corresponding reference portions 24, and then once again compares the corresponding portions to ascertain whether they are acceptably similar.

In accordance with an embodiment of the invention, evaluation 40 is performed only after an entire image portion 14 and corresponding reference image portion 24 is processed using the first algorithm set. It is noted however that interruption of an initial inspection using the first algorithm set to perform evaluation 40 may occur in various other sequences. For example, upon finding any location in an image portion 14 that is dissimilar from a reference portion 24, such as is seen at any location indicated by reference numeral 48, operation of the first algorithm set may be immediately interrupted. Then at a location 48, pattern portions, in a close vicinity surrounding corresponding but dissimilar parts of an image portion 14 and reference portion 24, are isolated, registered in a precise manner, and then compared using the second algorithm set to ascertain whether they are acceptably similar or unacceptably dissimilar.

In accordance with other embodiments of the invention, in order to determine whether a localized region in pattern 16 found by the first algorithm set is defective or not defective, the second algorithm set preferably employs inspection criteria which are additional to the criteria employed by the first algorithm, and/or criteria which are different from the criteria which are employed in the first algorithm. Although a localized region may be deemed possibly defective by using quickly applied simplified criteria in the first algorithm, further analysis thereof using additional and/or different criteria in the second algorithm set may indicate that the evaluated localized region is nonetheless not defective.

In accordance with a preferred embodiment of the invention, both the initial comparison, for example comparison employing the first algorithm set, and the second stage evaluation 40 may be performed on the same processor, preferably in an interleaved manner. It is appreciated that although the processing shown in FIG. 1 as being run on a first in first out basis whereby each image portion 14 is evaluated by a first algorithm and then if necessary an entire dissimilar image portion is evaluated by a second algorithm set in evaluation 40, before proceeding to initial comparison of a subsequent image portion 14, certain variations in the above-described method may be implemented.

Thus, optionally in an embodiment of the invention, an image stream may be acquired and stored in a first in first out manner. Once one or more complete image portions are collected, then a complete image portion is processed with the first algorithm set. In one alternative mode of operation, processing using the first algorithm set is immediately interrupted in order to evaluate any dissimilar location 48 in evaluation 40 whenever encountered. In another alternative mode of operation only dissimilar locations 48 are processed in evaluation 40, however all locations 48 that are encountered during processing of an image portion 14 using the first algorithm set, and only locations 48, are stored. Any stored locations 48 are then processed in evaluation 40 before processing a subsequent image portion 14.

It is noted that a feature of the invention resides in using at least two different algorithms, for example first algorithm set and second algorithm set, each having different resource and/or time requirements, in the same processor, preferably in adjacent time slots. Further features of the invention reside in that at least two different algorithms are used to process an image in an interleaved manner, and that one of the algorithms is less computational resource intensive than the other algorithm. The less resource intensive algorithm identifies the parts of the image which are to be further processed by the more resource intensive algorithm. When the more resource intensive algorithm is being used, operation of the less resource intensive algorithm is interrupted and a backlog of image portions is built up for processing by the less resource intensive algorithm. This time multiplexing is made possible by the first algorithm being able to operate at a rate faster than acquisition of image portions of a pattern to be inspected.

Moreover, by interleaving an initial comparison and a subsequent second stage evaluation as described hereinabove, the sum of the accumulated elapsed time for the stage of initial comparing corresponding image and reference portions together with the accumulated elapsed time for subsequently performing the various second stage evaluation processes does not significantly exceed the total time required for acquiring the image inspected. Thus, in the context of electrical circuit inspection, the same processor may be employed to analyze an image using at least two different algorithms, as described hereinabove, to ascertain the presence of defects in an electrical circuit in approximately in the same time period that is required to scan an entire electrical circuit being inspected.

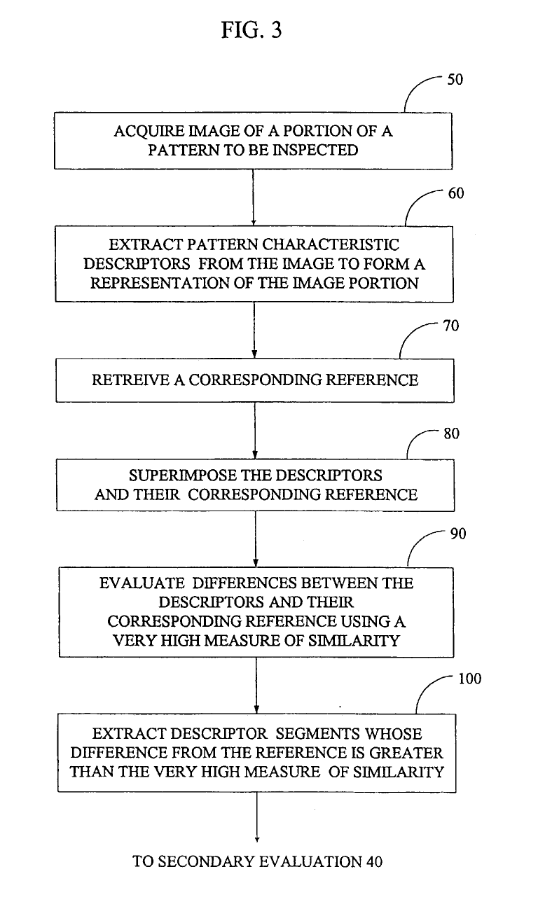

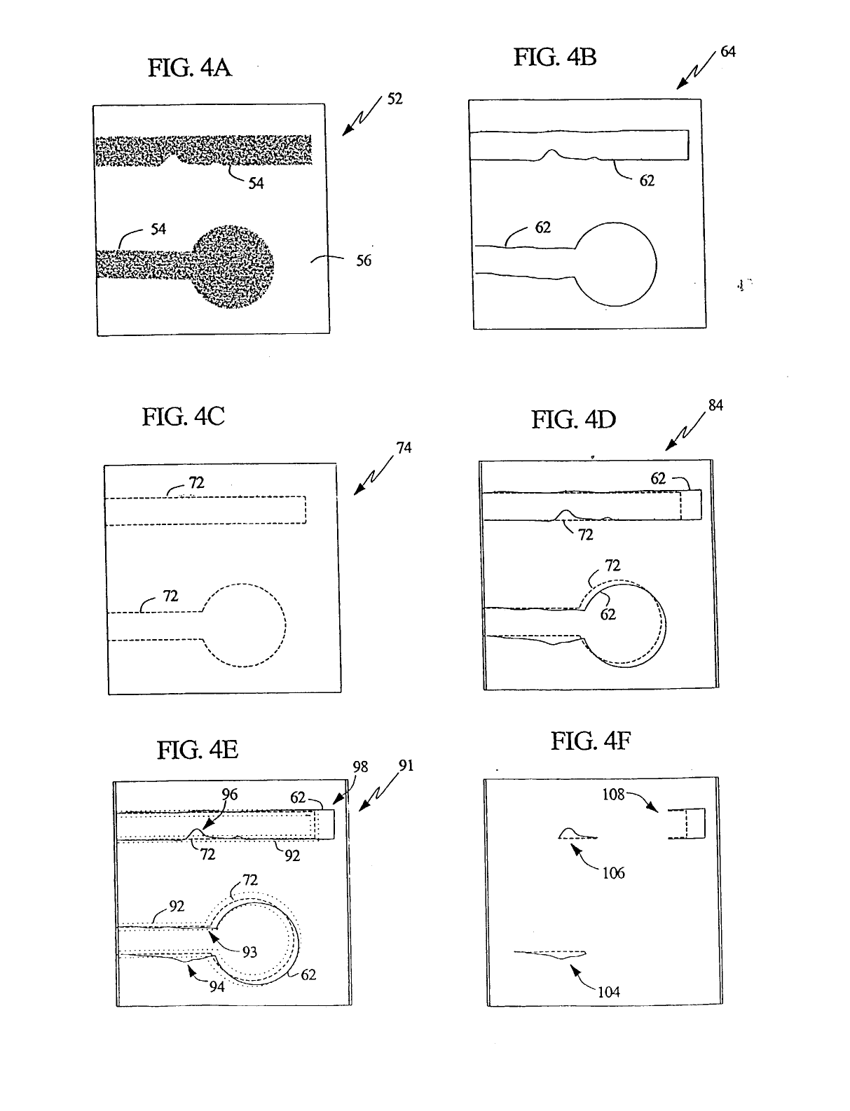

Reference is now made to FIG. 3 which is a flow diagram of the initial inspection functionality of FIG. 1 in accordance with an embodiment of the invention, and to FIGS. 4A-4F, which are simplified pictorial illustrations of the results of the steps in FIG. 3 in accordance with a preferred embodiment of the invention.

The initial inspection functionality begins with acquiring an image of a portion of a pattern to be inspected (step 50), for example an electrical circuit pattern. The image may be of an entire pattern to be inspected or a portion thereof. FIG. 4A shows an image portion 52 of part of an electrical circuit. Image portion 52 is an enlargement of the image portion 14 at location 5C in FIG. 1. Image portion 52 shows an image of a portion of conductor members 18, designated conductor image 54, against the background of a portion of surface 20, designated surface image 56.

It is a feature of embodiments of the present invention that a representation of a pattern to be inspected containing relevant information descriptive of characteristics of the image, preferably in a compressed form, is employed in or order to inspect a pattern. The inventors have found that contours are suitable characteristic descriptors of an electrical circuit to be inspected, and that in the context of optical inspection of electrical circuits, contours contain the information necessary to optically inspect electrical circuits for defects. Contours in an electrical circuit image represent the location of a transition between image portions representing conductors, for example conductors 18 in FIG. 1, and image portions representing a surface, for example surface 20.

In step 60 pattern characteristic descriptors are extracted from image portion to be inspected to form a representation of the pattern suitable for automated inspection by computer. FIG. 4B shows contours 62, which are suitable pattern characteristic descriptors, in a contour representation 64 of image portion 52. As seen in FIG. 4B, contours 62 are depicted as finite lines defining the edges of conductor image 54. It is appreciated that in an image, such as a digital image, contours may be a collection of pixels which represent an edge of conductor image 54. Alternatively, contours 62 may be a sub-pixel size linear representation of the edges of conductor image 54, known as CELs or contour elements, or any other suitable representation of a transition between different portions of a pattern, such as between conductors 18 and surface 20 in electrical circuit 16.

In step 70 a reference corresponding to the characteristic descriptors is retrieved. The reference is a construct of characteristic descriptors in a known to be non-defective pattern in comparison to which a pattern to be inspected is inspected for defects. FIG. 4C illustrates a set of reference contours 72 in a reference contour portion 74. Reference contour portion 72 contains contours which are to be expected in a contour representation 64 of an image portion 52 of a non defective electrical circuit.

In preferred embodiments of the invention, image portions 52 are acquired and are processed in an online manner generally simultaneously with image acquisition. An image of an electrical circuit to be inspected is maintained in dynamic registration, as it is being acquired, with a corresponding reference using, for example, methods generally as described in U.S. Pat. No. 5,495,535, the disclosure of which is incorporated herein by reference. In accordance with embodiments of the invention, reference portion 74 is prepared in an offline process, for example by extracting reference contours from an image of an electrical circuit which is know to be not defective, or from CAM image employed in the manufacture of an electrical circuit to be inspected. The alignment between contour representation 64 and reference contour representation 74 is maintained in order to ensure that a suitably corresponding reference is selected for each contour representation that is to be processed to detect defects.

In step 80 the corresponding pattern descriptors of a pattern to be inspected and a reference pattern are superimposed one on the other to facilitate comparison and identification of differences between the two representations. FIG. 4D illustrates the superimposition of contour representation 64 (solid lines) and reference contour portion 74 (broke lines) to form a superimposed image 84. In accordance

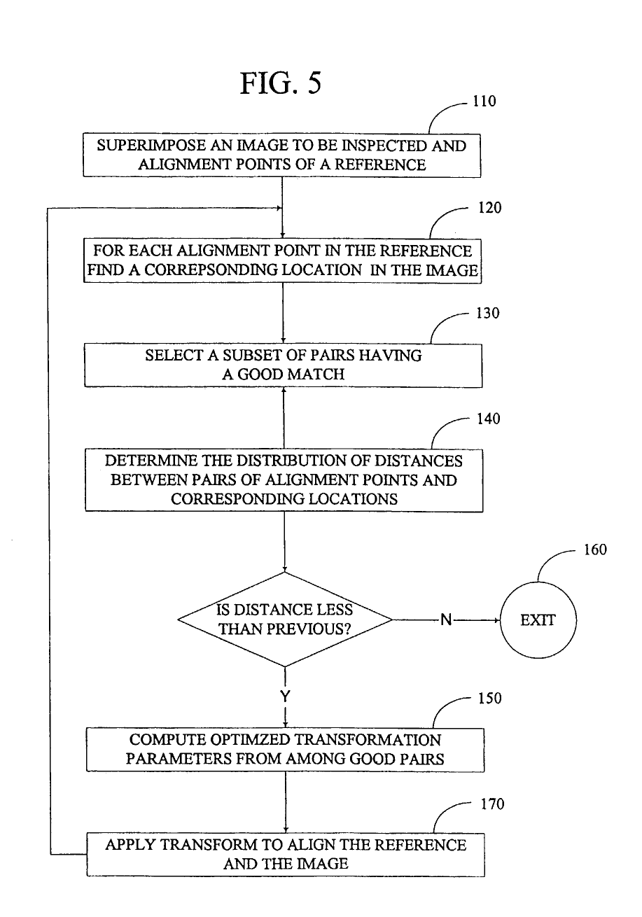

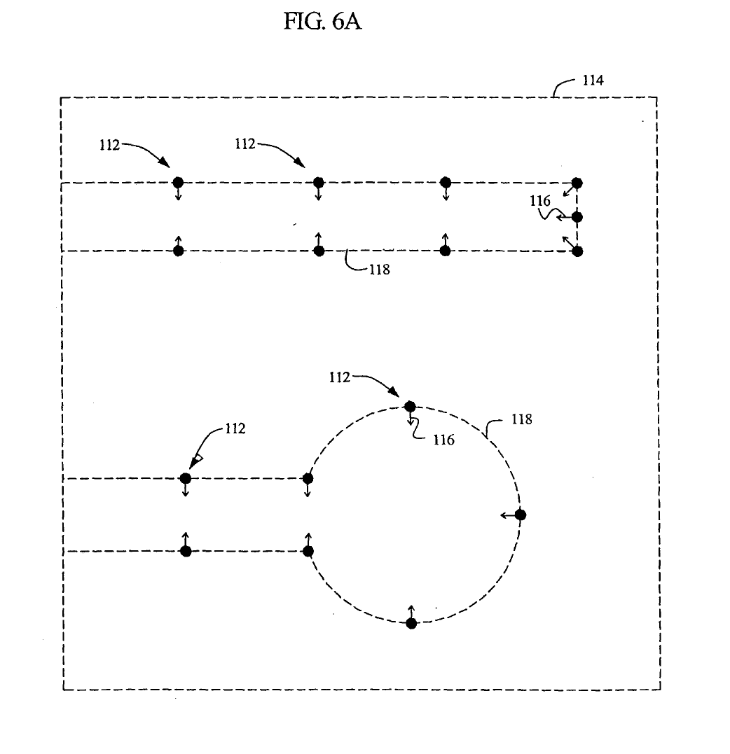

ith embodiments of the invention, step 80 includes an intermediate step of micro registering contour representation 64 and reference contour portion 74 to ensure precise alignment between the two representation. The micro-registration process is described in detail hereinbelow with reference to FIGS. 5-6B.

In Step 90 differences between the superimposed characteristic descriptors of a pattern to be inspected and a corresponding reference are evaluated using a very high measure of similarity. Those parts of the characteristic descriptors which are very highly similar to corresponding descriptors in the reference are deemed representative of a non-defective pattern portions, and are discarded from further evaluation.

FIG. 4E illustrates such evaluation of the difference between contours 62 and reference contours 72 in a superimposed representation with similarity thresholds 91 in accordance with a preferred embodiment of the invention. In the superimposed representation with similarity thresholds 91 a very high measure of similarity is represented by quality threshold indictors 92 (dotted lines). In accordance with a preferred embodiment of the invention, the evaluation of similarity is based on the spatial location of corresponding contours 62 and reference contours 72 in superimposed image 84. Thus quality threshold indicators 92 represent thresholds for distinguishing between segments of contour 62 which are sufficiently similar to reference contour 72 so as to be discarded from further consideration, and segments of contours 62 which are so different so as to be considered suspected defects that require secondary evaluation. All segments of contour 62 that lay between reference contour 72 and a threshold indicator 92 in representation 91 are considered similar to a corresponding segment of reference contour 72 and do not require further evaluation. Segments of contour 62 that lay are outside the area bounded by threshold indicators 92 surrounding a reference segment 72 are considered dissimilar to a corresponding segment of reference contour 72, and thus representative of a suspected defect that requires secondary evaluation.

The distance of quality threshold indicator 92 from reference contour 72 may be adjustable, for example by setting an inspection sensitivity parameter, so as to provide greater or lesser sensitivity in finding suspected defects in the stage of initial inspection. In preferred embodiments of the invention it is desirable to set thresholds 96 and 98 holds 96 and 98 very close to segment 72. Making the distance of threshold 92 from reference contour 72 smaller increases the sensitivity in detecting suspected defects. As a result, a relatively high rate of detecting falsely positive defects and relatively low rate of missing real defects. The suspected defects are subsequently further evaluated in the secondary evaluation stage 40 (FIG. 1B). The choice of a suitable distance of threshold 92 from reference contour 72 is a design consideration that is made, for example, as a function of a desired detection sensitivity, and the capacity of the secondary evaluation stage 40 to handle and evaluation a smaller or larger quantity of suspected defects.

Four segments of contour 62, designated reference numerals 93, 94, 96, 98 and 99, are shown in FIG. 4E as exhibiting a visually discernable difference respective of the corresponding reference contour 72. A permissibly different segment 93 is different from a corresponding segment in reference contour 72, however it is located entirely inside the area bounded by a pair of thresholds 92. Excessively different segments 94, 96, and 98 each at least partially extend outside the area bounded by respective pairs of thresholds 92.

In step 100 descriptor segments whose difference from the corresponding reference contour 72 is greater than a measure of permissible difference are extracted, and then supplied to secondary evaluation 40 (FIG. 1B). All of descriptor segments that are the same as the reference, or that are permissible different as defined by the very high measure of similarity, such as at segment 93, are discarded from further evaluation. It is appreciated that a descriptor segment extracted for secondary evaluation needs to be sufficiently dimensioned so that it can be suitably evaluated in the secondary evaluation process.

FIG. 4F illustrates pairs of excessively different segments 104, 106 and 108 of contours 62 and their corresponding reference contours 72 which are extracted, in accordance with an embodiment of the invention, in step 100. Other segments, including permissibly different segment 93, are all discarded and are not further processed. It is noted that each of pairs 104 and 106 do not include just the section of contour 62 that is actually outside of a threshold 92. Rather, pairs 104 and 106 include at least a portion of a contour 62 that is located at least partially outside the area between a threshold 92 and reference contour 72. In addition pairs 104 and 106 are bounded on either side by a portion of the contour 62 up to a location where it intersects reference contour 72. It is appreciated that other suitable methods for choosing a segment to extract may be employed. For example, as seen with reference to excessively different segment 108 a suitable segment to be extracted may be chosen as a function of an arbitrary distance bounding any portion of a segment 62 that extends outside of the area between a threshold 92 and a reference contour 72.

The above types of selection of suitable image portions for secondary inspection are by no way intended to be limiting, and any other suitable selections of image portions or segments may be provided to secondary inspection. Thus, by way of additional example, whenever an excessively different segment is encountered, a representation encompassing two adjacent contour segments, each corresponding to opposite edges of a conductor, are selected and provided to secondary evaluation. This is useful, for example, in ascertaining whether the excessively different segment causes a defect, such as a short, an open or an unacceptable width restriction, in a conductor 18 of an electrical circuit. As an additional example, in FIG. 1 it is seen that a two dimensional image portion is provided to evaluation 40 whenever any part in an image portion 14 differs from a corresponding reference image portion by greater than a predetermined threshold. As noted, this need not be the case since, as seen with reference to FIGS. 4A-4F, only excessively different segments may be provided to evaluation 40.

Reference is now made to FIG. 5 which is a simplified flow diagram of a process for micro-registering acquired image portions and corresponding reference portions employed in embodiments of the invention, and to FIGS. 6A-6B which are schematic diagrams illustrating several aspects of the micro-registration process of the process of FIG. 5. The micro-registration process preferably an iterative process, beginning with step 110, in which an image portion to be inspected is superimposed in general alignment with a reference portion. General alignment of the image portion to be inspected and the reference may be obtained, for example, using a global alignment algorithm, or any other suitable alignment process, such as is described in U.S. Pat. No. 5,495,535, the disclosure of which is incorporated herein by reference. For the purpose of micro registration, the reference portion contains a set of alignment points 112, for example points that are assigned arbitrarily or according to a set of predetermined rules, that are employed to precisely align the reference portion to the image portion which is to be inspected.

FIG. 6A shows several alignment points, generally designated reference numeral 112, in a reference portion 114. Each alignment point 112 has associated therewith an arrow, or vector, 116. Arrows 116 indicates the direction of a gradient, for example a gray level gradient indicating a direction of transition from substrate to conductor in an electrical circuit, at that location. The respective directions of the gradient indicated by arrows 116, are employed to find, in an image portion to be inspected, a matching point for each alignment point 112. It is noted that, for purposes of simplicity of illustration, alignment points 112 are shown in substantial enlargement. However, alignment points preferably are made as small as possible. FIG. 6B shows the superimposition, in general alignment after global alignment but before micro-alignment, of reference 114 and an image portion to be inspected 117. The process illustrated in FIG. 5 more precisely aligns reference portion 114 and portion to be inspected 117 then as shown in FIG. 6B.

In the example seen in FIG. 6A, all of the alignment points 112 are located along contours 118. Alignment points may, however, be distributed in a reference in any suitable manner for which corresponding points in an image to be inspected may be found. In various embodiments of the invention alignment points 112 are selected or assigned in an offline process during which a reference 114 is prepared. It is desirable to select alignment points such that the set of alignment points has a generally uniform directional distribution of gradients, for example as would be found among gradients along the perimeter of a circle. It is appreciated that the quantity of alignment points chosen is a system parameter that is determined, for example, empirically. A greater quantity of alignment points can increase the precision of alignment, however a greater amount of computational resources is required to process a relatively large number of alignment points as compared to a relatively small number of alignment points.

In step 120 matching locations, designated reference numerals 122 in FIG. 6B, are found in the image portion to be inspected for at least some alignment points 112 in reference 114. In accordance with embodiments of the invention, a matching location 122 is found by extending a ray 124 from each alignment point 112 in the direction of the arrow 116 associated therewith each alignment point. Thus a matching location 122 for an alignment point is that location which is situated at the intersection of a ray 124 and a contour 126 in the image portion to be inspected.

Typically, not all matching locations are suitable to be used in a micro-registration process. Thus, in accordance with an embodiment of the invention, in step 130 a subset of pairs of alignment points 112 and matching locations 122 which have a good match are selected. A good match is an alignment point and matching location pair which is suitable for use in a micro-registration process, as may be determined by any suitable parameter. For simplicity of illustration, only good matching locations are seen in FIG. 6B. In the example seen in FIG. 6B, the parameter employed is a predetermined distance, shown as a perimeter 126, from an alignment point 112. Matching locations which are not located inside a perimeter 126 typically are associated with contours in an image portion to be inspected 117 that do not correspond to the reference contour 118 along which an alignment point 122 is located. It is appreciated that other suitable parameters, for example parameters including a direction, a location in an image or a weighting of several characteristics may be employed to determine a suitable match between an alignment point and a matching location.

In preferred embodiments of the invention, the alignment process is carried out in several iterations, or through suitable mathematical analysis, until either the closest possible alignment is obtained, or until a desired level of precision is obtained. In step 140 the distances, namely the distance between an alignment point and its matching location, among the subset of pairs having a good match is summed, recorded, and compared to any previously computed distances among good pairs of alignment points 112 and their matching locations 122. If the distance is obtained from a first iteration, or if the distance among pairs of alignment points and matching locations is less than the distance computed in a previous iteration, then the micro-registration process proceeds to step 150 in which an optimized transform parameter is computed from among the good matching pairs. However, if the sum of distances between alignment points 112 and matching locations 122 is greater than the distance computed in the previous iteration, or if it meets some other parameter such as predetermined level of acceptable precision, then the process exits at exit 160.

Transform parameters are computed in step 150 for one or more of scaling, X direction translation, Y direction translation, rotation, or any other suitable parameter or set of parameters. In accordance with preferred embodiments of the invention, the transform is computed so as to minimize the least squares distance between matching pairs of alignment points and matching locations for each of the desired parameters.

In step 170 the transform parameters are applied to the image portion to be inspected 117 which is magnified (or demagnified), rotated and translated in accordance with the transform parameters computed in step 150. Following application of the transform parameters in step 170, the micro-registration process loops back to step 120 for a further iteration until a suitably alignment of the reference and the image to be inspected is obtained, as seen, for example in FIG. 4D. It is appreciated that in each iteration of the micro-registration process, a new set of corresponding locations and good matches is identified and selected.

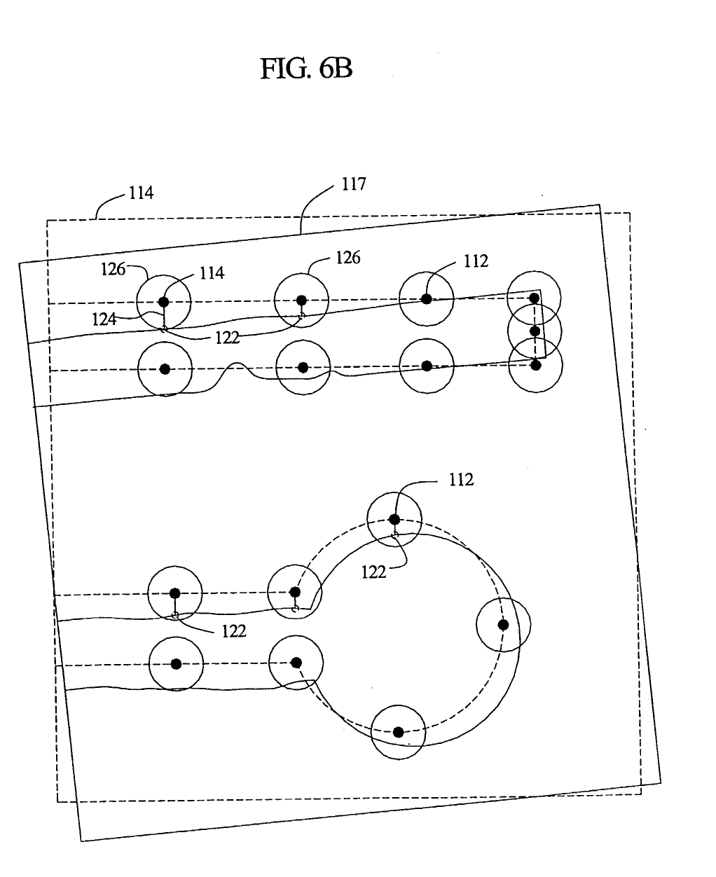

Reference is now made to FIG. 7 which is a simplified flow diagram of a process 200 for performing an evaluation of suspected defects in accordance with an embodiment of the invention. Process 200 preferably is employed in preferred embodiments of the invention in the second stage evaluation 40 shown in FIG. 1B. In step 210 pattern characteristic descriptors of a suspected defect in an image portion that is being inspected are received for processing along with a corresponding reference. An example of pairs of pattern characteristic descriptors of a suspected defect and a corresponding reference is seen in FIG. 4F, which illustrates pairs of excessively different segments 104, 106 and 108 of contours 62 and corresponding reference contours 72.

In accordance with preferred embodiments of the invention, in step 220 the pattern characteristic descriptors of a suspected defect are locally microregistered with the corresponding reference. The local microregistration process of step 220 is similar to the microregistration process described with reference to FIGS. 5-6B, however it differs from that microregistration process in that it is performed locally only on the pattern characteristic descriptors of a suspected defect and its corresponding reference, an not on an entire image portion. The micro-registration may use the same alignment points used in the process of FIG. 5. Optionally, a new set of alignment points is provided, for example alignment points that are uniformly or otherwise distributed in the reference.

After the pattern characteristic descriptors for a suspected defect are micro-registered with a corresponding reference, in step 230 the difference between the pattern characteristic descriptors and the reference is evaluated with respect to a predetermined measure of similarity. In some embodiments of the invention, the pattern characteristic descriptor is a contour in an image portion to be inspected, and the measure of similarity is a geometric distance between the contour segment relating to a suspected defect and its corresponding reference portion. The measure of similarity may be the same measure of similarity as is employed in step 90 (FIG. 3) and indicated by quality threshold indictors 92 (FIG. 4E). Optionally, a greater or lesser measure of similarity may be employed or several measures of similarity may be employed according to predetermined logic.

Finally, in step 240 those suspected defects whose pattern characteristic descriptors exhibit a difference from their corresponding reference which is greater than the predetermined measure of similarity are reported as real defects. The real defects may be included in a defect report. Alternatively, real defects may be further processed to classify defects or to identify a subset of the real defects in an offline or post process. Additionally or alternatively, the second stage evaluation may be employed as a second stage filter, and a third set of algorithms, forming a further level of evaluation, in addition to evaluation 40, is applied only to those pattern characteristic descriptors designated as real defects to identify a subset of the real defects.

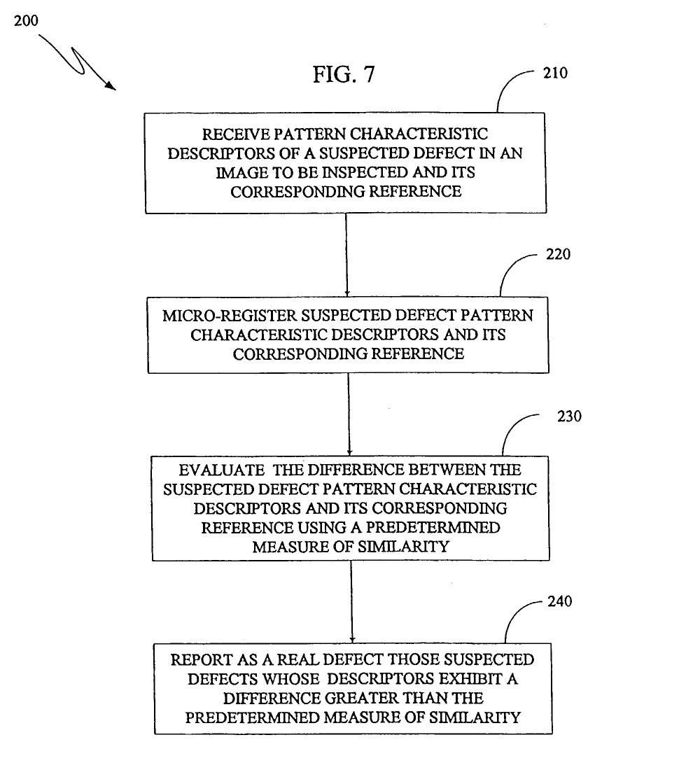

Reference is now made to FIGS. 8A-10B which are simplified pictorial illustrations of an evaluation process 200 as applied to each of pairs of excessively different segments 104, 106 and 108 (FIG. 4F), in accordance with a preferred embodiment of the invention.

In FIG. 8A a second pair of excessively different segments 104, including a segment to be evaluated 262 and a reference segment 264, along with high quality threshold indicators 92 used in the process of FIG. 3, are shown. It is noted that segment 262 partly extends outside of the area bounded by indicators 92 and is thus a suspected defect. In step 220 segment 262 and reference 264 are locally microregistered. The result of local microregistration, in which segment 262 is translated and rotated relative to reference 264, is seen in FIG. 8B. FIG. 8B shows permissible distance indicators 266 which are employed in step 230 to evaluate whether segment 262 is sufficiently similar to reference 264 so as to meet the predetermined measure of similarity. It is noted that after local microregistration segment 262 partly extends outside of the area bounded by permissible distance indicators 266 at location 268. Because segment 262 extends partly outside the area bounded by permissible distance indicators 266, in step 230 it is evaluated as failing to meet the predetermined measure of similarity and thus, in step 240 (FIG. 5), segment 262 is reported as being an actual defect.

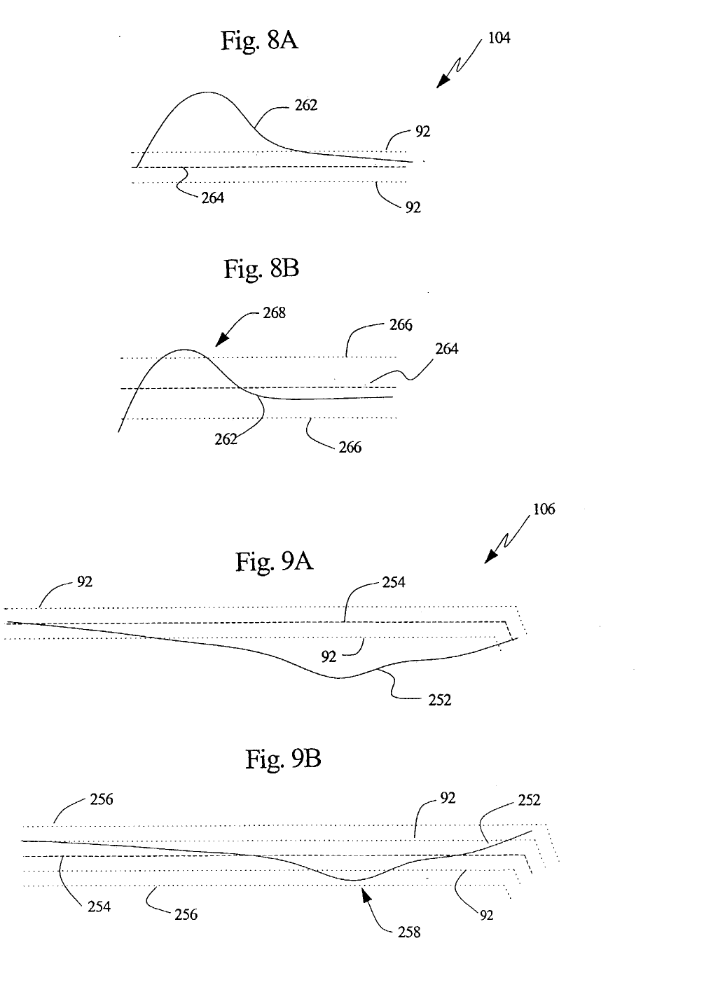

In FIG. 9A a first pair of excessively different segments 106, including a segment to be evaluated 252 and a reference segment 254, along with high quality threshold indicators 92 used in the process of FIG. 3, are shown. It is noted that segment 252 partly extends outside of the area bounded by indicators 92 and is thus a suspected defect. In step 220 segment 252 and reference 254 are locally microregistered. The result of local microregistration, in which segment 252 is translated and rotated relative to reference 254, is seen in FIG. 9B. FIG. 9B also shows permissible distance indicators 256 which are employed in step 230 to evaluate whether segment 252 is sufficiently similar to reference 254 so as to meet the predetermined measure of similarity. It is noted that permissible distance indicators 256 are located further from reference segment 254 than indicators 92, indicating that after local micro-registration a greater degree of difference is permissible between segment 252 and its corresponding reference segment 254 without segment 252 being considered indicative of an actual defect. After local microregistration segment 252 still partly extends outside of the area bounded by high quality threshold indicators 92 at location 258. It is also noted that segment 252 is located entirely inside of the area bounded by permissible distance indicators 256. Because segment 252 is located entirely inside of the area bounded by permissible distance indicators 256, in step 230 it is evaluated as meeting the predetermined measure of similarity and thus, in step 240, segment 252 is not reported as being an actual defect.

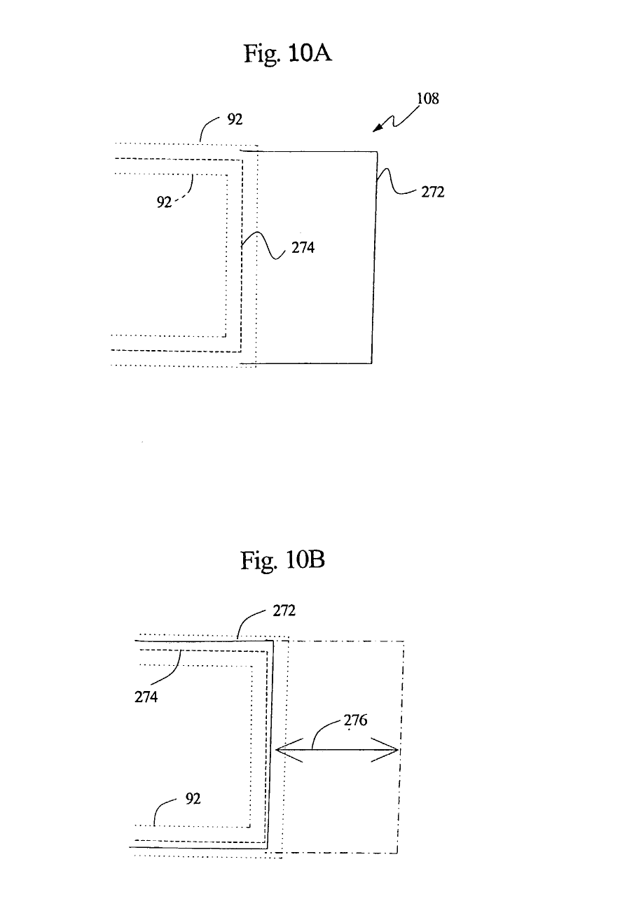

In FIG. 10A a first pair of excessively different segments 108, including a segment to be evaluated 272 and a reference segment 274, along with high quality threshold indicators 92 used in the process of FIG. 3, are shown. It is noted that segment 272, although similar in shape to reference 274, is set apart from reference 274. In accordance with an embodiment of the invention, one of the measurements by which a segment to be evaluated is evaluated for its similarity to a reference is the distance by which it is translated in the microregistration process.

Because segment 272 is located at least partially outside an area bounded by indicators 92, it is a suspected defect. In step 220 segment 272 and reference 274 are locally microregistered. The result of local microregistration, in which segment 272 is laterally translated relative to reference 274, is seen in FIG. 10B. FIG. 10B also shows high quality threshold indicators 92. It is seen that inasmuch as segment 272 lies entirely inside indicators 92, it is highly similar in shape to reference 274, however it has been translated a distance indicated by arrows 276. In accordance with an embodiment of the invention, if the distance of translation exceeds a predetermined, typically parameterized, value, then the segment is deemed an actual defect even though it may be nearly identical in shape to the reference. Such a translation indicates, for example, that a conductor represented by segment, although properly formed, is not located at the location where it is expected to be located in an electrical circuit pattern being inspected. It is appreciated that such a threshold may be applied, additionally or alternatively, to other aspects of the microregistration transform, for example rotation or scaling.

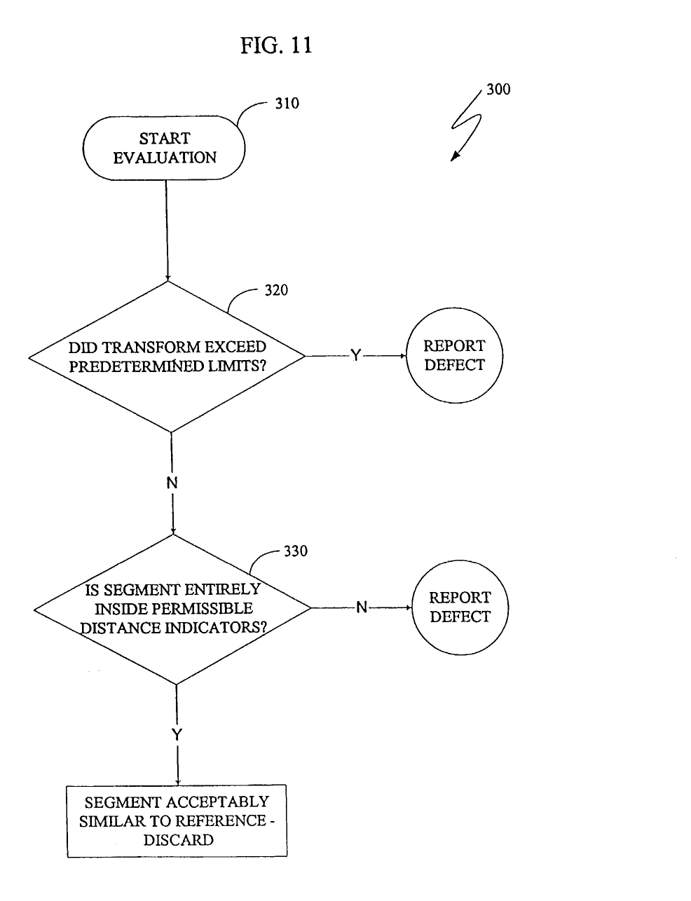

Reference is now made to FIG. 11 which is a simplified flow diagram of a preferred evaluation methodology 300 for performing an evaluation step in the process of FIG. 7. The evaluation begins in step 310 with the receipt of a segment to be evaluated and a reference segment in nicroregistered alignment, along with data indicating the extent of transformation for one or more of the following: X translation, Y translation, rotation scaling or any other desired transformation data. In embodiments of the invention, in step 320 the transformation data is evaluated to ascertain whether the transformation exceeds one or more thresholds relating, for example to translation, rotation or scaling. The evaluation may be based on weighted values, for example with more or less relative weight being given to translation than to rotation or scaling. Additionally or in the alternative, such evaluation may include a summation of several transformation parameters. If the result of evaluation of the transformation exceeds a threshold value, then an actual defect is reported. If the transformation is deemed acceptable, then in step 330 the segment is further evaluated to determine whether or not it is located entirely within a permissible distance from the reference, for example as indicated by permissible distance indicators 256 (FIG. 8) and 276 (FIG. 9). If the segment is located partly outside the permissible distance from the reference an actual defect is reported. However if the segment is located entirely within the permissible distance, then it is deemed acceptably similar to the reference. It is discarded from further evaluation and other inspection steps are performed on other parts of an image of a pattern being inspected.

It is noted that the respective evaluations in each of steps 320 and 330 may take place in the reverse order. Moreover it is noted that in the context of electrical circuit inspection, each of the steps 320 and 330 are effective to analyze different types of defects. Thus, for example, the evaluation in step 320 is effective in detecting defects in which features, such as pads and conductor ends, in an electrical circuit are present and formed in the proper geometric shape however they are placed an incorrect location. It is also effective in evaluating whether the width of a conductor is formed too wide or too narrow. The actual location of a feature may be as close to or as far away from an absolute location as indicated in an inspection parameter. The actual width of a conductor as close to or as far away from desirable width as indicated in an inspection parameter. Such incorrect location or width may be the result, for example, from drift and other factors in pattern exposure and etching processes.

On the other hand, the evaluation in step 330 is effective in detecting defects in which features, such as pads, conductors and conductor ends are generally positioned the desired location, however their geometric shape is incorrectly formed. Examples of incorrect geometric shape include nicks and protrusions along the length of what should be a conductor formed with generally smooth edges.

In accordance with another embodiment of the invention, evaluation 40 (FIG. 1B) employs a different process to analyze and evaluate excessively dissimilar segments. Excessively dissimilar contour segments are abstractly represented, for example as a polygon, and the abstract representation is compared to an abstract representation of a corresponding reference to detect actual defects. One way to abstractly represent contour segments is as a polygon in which the shape of the polygon is derived from various features and characteristics of a contour segment. Suitable features and characteristics are, for example, those features and characteristics which enable an inspection system to distinguish between good and bad contour segments.

A set of features and characteristics which is useful in the detection of defective contour segments in electrical circuit inspection, in accordance with an embodiment of the invention, is a collection of statistical moments representing the planar distribution of points along a contour to be inspected. Suitable moments include, for example, those moments corresponding an X-Y coordinate corresponding to a center of gravity of points along a contour, and an angle of rotation of the contour, a distribution of points along a first axis in the direction of the angle of rotation, and a distribution of points along a second axis normal to the first axis. For the purpose of conceptualization, these characteristics of a contour may be graphically represented as a polygon, in the form of a rectangle. Thus in accordance with embodiments of the invention, evaluation of the segment is accomplished by comparing such a polygon to a polygon representing a reference segment.

It is noted that by abstractly representing a contour segment in the manner described as a polygon indicative of the distribution of points forming the contour, various localized aberrations in the shape of the contour, which render it different from a corresponding reference contour, are smoothed out or ignored entirely. As a result, evaluation of a contour segment can concentrate on considering characteristics indicative of an entire segment while ignoring localized aberrations that falsely indicate a defect. Moreover, by representing a segment as a collection of features and characteristics, various features and characteristics of the segment can be readily weighted to ensure a suitable balance among the various features for determining a level of desired similarity between a contour to be inspected and its corresponding reference.

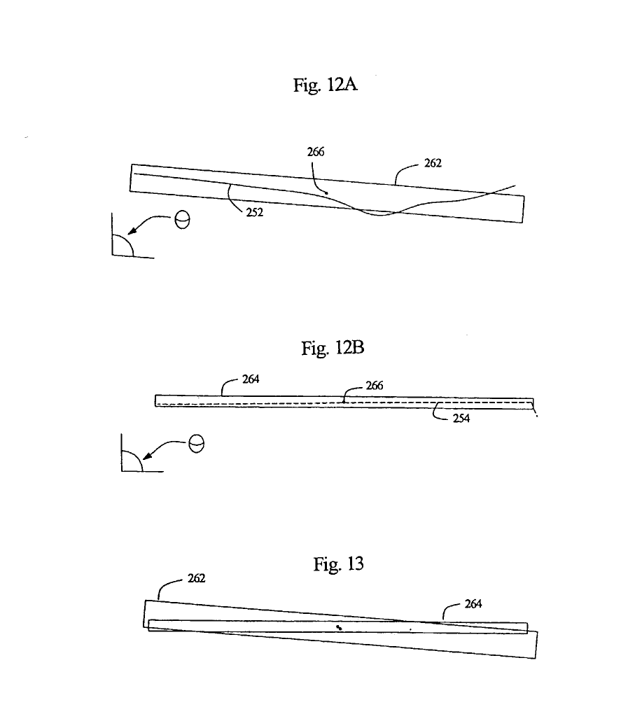

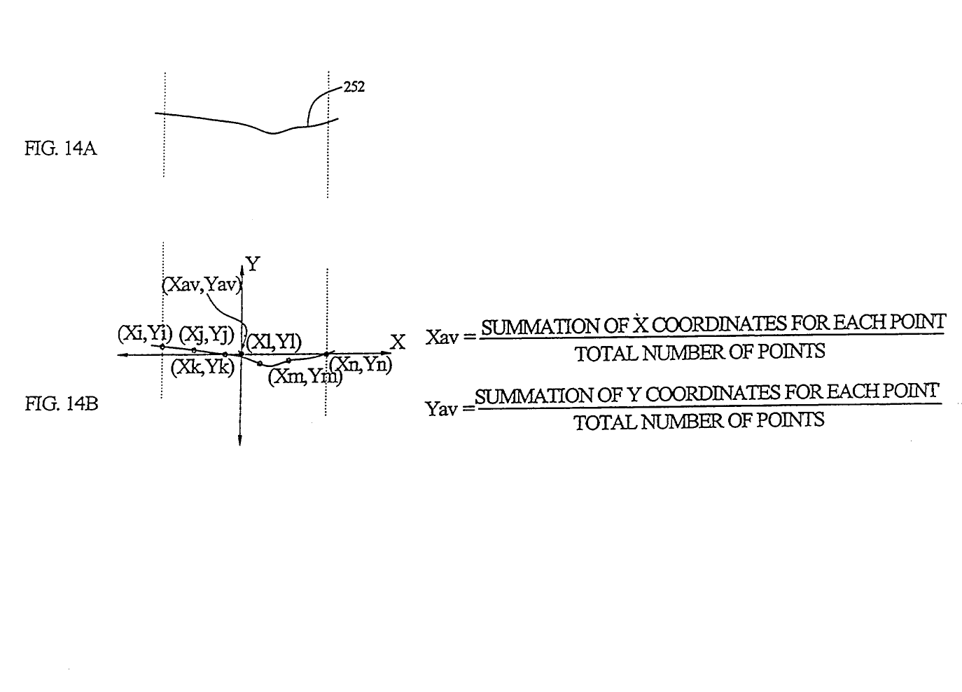

Reference is now made to FIGS. 12A and 12B which are simplified pictorial illustrations of an excessively dissimilar segment 252, a corresponding reference 254 and abstract representations of dissimilar segment 252 and reference 254, labeled reference numerals 262 and 264 respectively. Reference is further made to FIG. 13 which is a simplified pictorial illustration of the superimposition of the abstract representations 262 and 264 in accordance with an embodiment of the invention. The superimposition of the abstract representations of a contour segment and its reference is employed to evaluate whether an excessively dissimilar segment is an actual defect.

In FIGS. 12A and 12B it is seen that abstract representations 262 and 264 are rectangular polygons, each having a center point 266, an angle of rotation θ, a length, a width. In accordance with an embodiment of the invention, a center point 266 represents the average coordinate of selected points in a contour segment to be evaluated. The angle of rotation θ represents an angular distribution of selected points in the contour segment. The length of the rectangle represents the distribution of selected points in the contour along an axis in the direction of the angle of rotation, and the width of the rectangle represents the distribution of selected points in the contour along an axis normal to the axis in the direction of the angle of rotation.

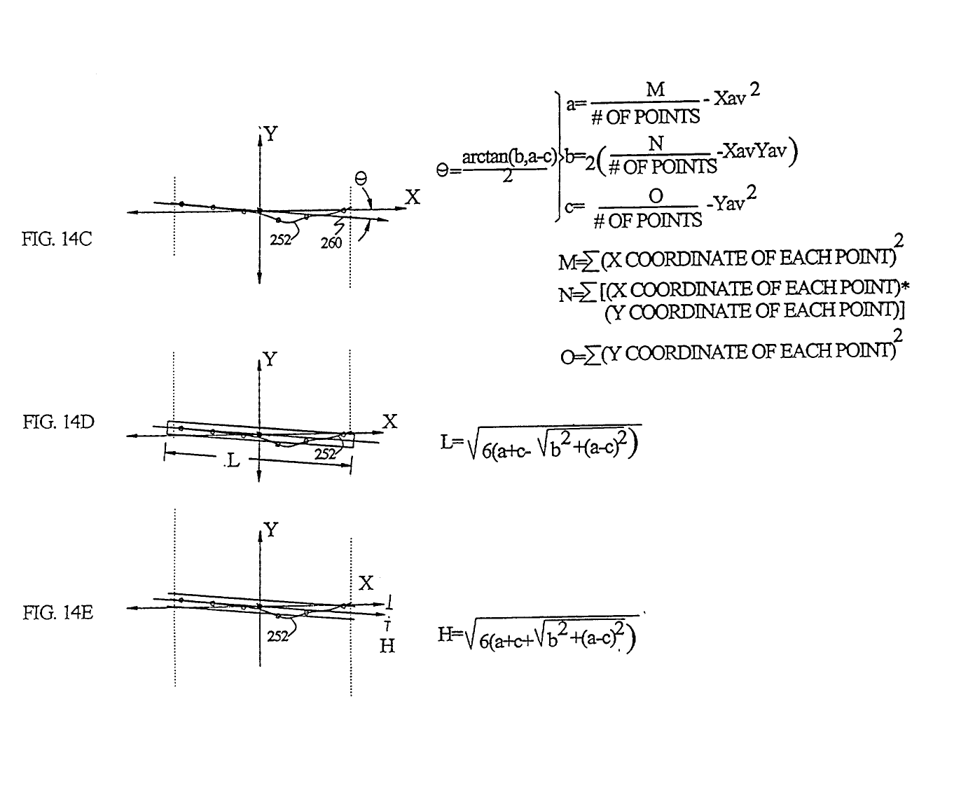

Reference is now made to FIGS. 14A-14E which are a simplified pictorial illustrations of a computational methodology suitable to derive a polygon abstractly representing a contour to be evaluated in accordance with an embodiment of the invention. Computation of a polygon, using preferred formulae, is shown with reference to excessively dissimilar segment 252 (FIG. 14A).

As seen in FIG. 14B, the center point of contour segment 252 is represented by a coordinate Xav-Yav, which is computed by averaging the respective X-Y coordinates of selected sampling points in segment 252. For the simplicity of explanation, only sampling points i, j, k, l, m, and n are shown. It is appreciated that precision of the location of the center point increases in relation to the quantity of sampling points used in the computation.

In accordance with an embodiment of the invention, the computation of the angle of distribution of segment 252, the length L of polygon 262 and the height H of polygon 262 are computed using the following values:

$$\begin{matrix}a = \frac{{Σ ( X COORDINATE OF EACH SAMPLING POINT )}^{2}}{\# OF \cdot SAMPLING \cdot POINTS } - {X}_{av}^{2} & ( 1 ) \\ b = 2 ( \frac{Σ [ \begin{matrix}( X \text{COORDINATE} OF EACH SAMPLING POINT ) \\ * ( Y COORDINATE OF EACH SAMPLING POINT )\end{matrix} ]}{\# OF \cdot SAMPLING \cdot POINTS } - {X}_{av} {Y}_{av} ) & ( 2 ) \\ c = \frac{{Σ ( Y COORDINATE OF EACH SAMPLING POINT )}^{2}}{\# OF \cdot SAMPLING \cdot POINTS } - {Y}_{av}^{2} & ( 3 )\end{matrix}$$

Consequently, in accordance with an embodiment of the invention, the angle of distribution of a segment, represented by an axis 260 disposed along an angle θ, such as segment 252 in FIG. 14C, is computed using the formula:

$$θ = \frac{arctan ( b , a - c )}{2} \qquad ( 4 )$$

The length L of a rectangular polygon representing the distribution of selected points in a contour along an axis of angular distribution, such as axis 260 for contour 252 in FIG. 14D, is computed in accordance with an embodiment of the invention using the formula:

$$L = \sqrt{6 ( a + c - \sqrt{{b}^{2} + {( a - c )}^{2}} )} \qquad ( 5 )$$

Finally, the height H of a rectangular polygon representing the distribution of selected points in a contour along an axis normal to axis of angular distribution, such as an axis normal to axis 260 for contour 252 in FIG. 14E, is computed in accordance with an embodiment of the invention using the formula:

$$H = \sqrt{6 ( a + c + \sqrt{{b}^{2} + {( a - c )}^{2}} )} \qquad ( 6 )$$

Returning now to FIG. 13, it is seen that once a polygon representation 262 of a contour to be evaluated is constructed, it is compared to a polygon representation 264 of a corresponding reference, as shown by superimposition of rectangular polygons 262 and 264. A determination of whether a contour segment is an actual defect is based on the degree of similarity or dissimilarity, called a distance, between the polygons.

The matching of similarly shaped polygon is known and generally described in H. Alt, B. Behrends, and J. Blomer, Approximate Matching of Polygonal Shapes, in Proceedings of the 7^{th} Annual Symposium on Computational Geometry, pp. 186-193, ACM Press, New York, N.Y., 1991, the content of which is incorporated herein by reference. It is appreciated that the polygons representing a contour to be evaluated and its corresponding reference need not be, and typically are not, an exact match. In accordance with embodiments of the invention, the distance between polygons 262 and 264 is evaluated respective of each parameter describing the polygon, for example center point location, rotation, length and width, and additionally by summing the respective distances of the various parameters and evaluating the summed distance with reference to a total acceptable distance threshold. A polygon may be deemed indicative of an actual defect if any individual parameter exceeds a predetermined maximum difference, for example the center point is translated by a greater distance than permissible relative to the center point of the reference, or if the sum of all the various differences exceeds an acceptable distance threshold.

Computation of the distance between a polygon representing a contour to be evaluated and the polygon of its corresponding reference may be multi-dimensionally interrelated. Thus, for example, if the angle of rotation of a polygon to be evaluated is relatively large, this distance may be compensated by other parameters relating to center point, height, and length being relative close to a desired value.

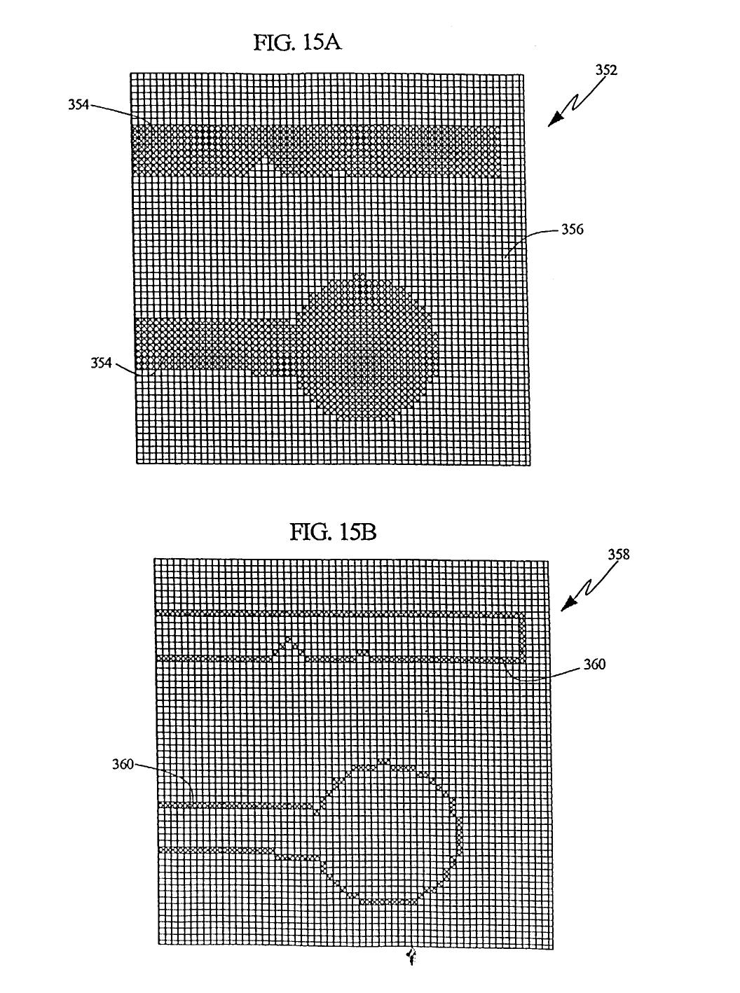

Reference is now made to FIGS. 15A and 15B which are simplified illustrations of a digital image of portion of an electrical circuit to be inspected, and of contour representations thereof used in the inspection process in accordance with preferred embodiments of the invention. It is noted that the description of the invention until this point has been made with reference to an inspection process employing patterns formed with generally continuous contours. In accordance with some embodiments of the invention, digitized images are acquired of patterns to be inspected, and contours are represented by collections of pixels.

FIG. 15A is simplified illustration of a digitized image portion 352, corresponding to image portion 52 in FIG. 4A. It is seen that digitized image portion 352 includes a plurality of pixels 354. Conductor pixels 354, shown in cross-hatch, represent the location of conductors 18 in FIG. 1, while substrate pixels 356, shown without cross-hatch, represent the location of surface 20 in FIG. 1.

A digital contour image 358 defining contours as a collection of contour pixels 360 is seen in FIG. 15B. In accordance with an embodiment of the invention, contour pixels 358 are those conductor pixels 354 in digitized image portion 352 which are bounded on at least one side by a substrate pixel 356. Contour pixels 360 may be extracted from any suitable gray scale or binary digitized image portion 352 of a pattern being inspected 16, such as an in fabrication electrical circuit.

In accordance with another embodiment of the invention various determinations as to whether a contour segment is excessively different from its reference, are made as a function of a distance between contour pixels in a digital contour image of pattern portion being inspected and a digital contour image of its corresponding reference. Thus in accordance with an embodiment of the invention a contour segment is deemed to be an excessively different contour segment, in the initial stage of inspection, if the location of one or more contour pixels differs by ±one pixel from the location of corresponding contour pixels in a digitized contour image of the reference. During second stage inspection, an excessively different segment is deemed an actual defect if it is translated by more than 3 pixels during a microregistration process, such as described with reference to FIG. 7, or if pixels in a contour segment are located at a distance greater than 2 pixels from corresponding pixels in a reference contour. It is appreciated that these values are exemplary values, and that they may be modified as a function of image resolution and/or as a function of a desired inspection sensitivity.

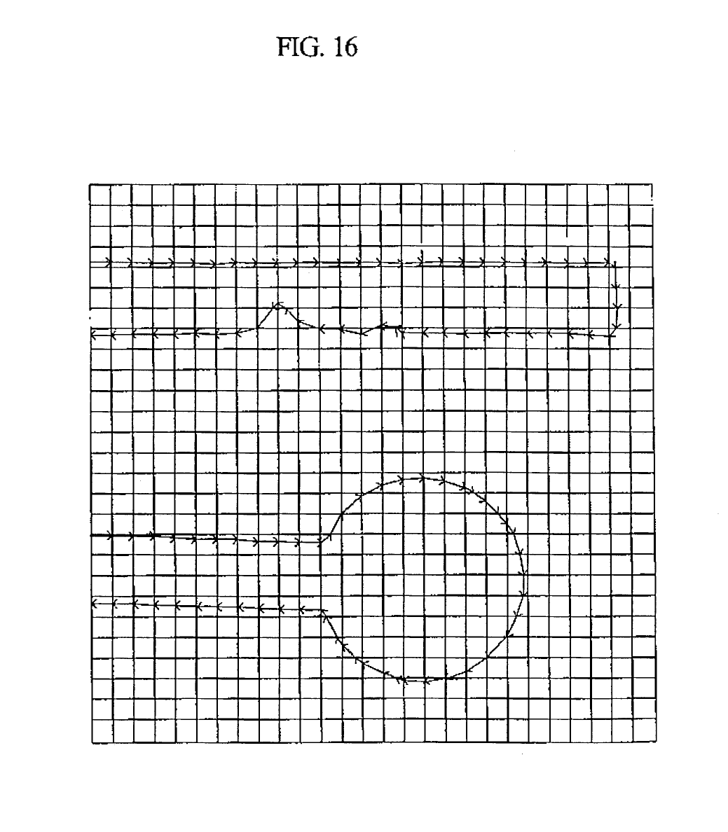

Reference is now made to FIGS. 16 which is a simplified pictorial illustration of a digital image of a portion of an electrical circuit to be inspected 452 defined by sub-pixel resolution contour elements 454. The sub-pixel resolution contour elements, shown as arrows, indicate a sub-pixel location of a contour in a digitized image. The extraction of sub-pixel information from gray level images, including producing images of patterns defined by sub-pixel contour elements, is well known. See for example, U.S. Pat. Nos. 5,774,572, 5,774,573 and pending U.S. patent applications Ser. Nos. 09/633,756 and 09/782,626, the disclosures of which are incorporated herein by reference. In accordance with preferred embodiments of the invention, sub pixel resolution contour elements in representations of patterns to be inspected are compared and evaluated with respect to a reference image, typically formed of vectors representing contours, as described hereinabove to locate actual defects in patterns.

It is appreciated by persons skilled in the art that the present invention is not limited to what has been particularly shown and described hereinabove. Rather, the scope of the present invention includes various features and combinations of features described hereinabove as well as modifications and additions thereto which would occur to a person of skill in the art upon reading the foregoing description and which are not in the prior art.

1. A method for the inspection of electrical circuit patterns, comprising:
carrying out an initial inspection of a sequentially acquired image of an electrical circuit pattern to determine potential defects in said electrical circuit pattern;
upon identifying a potential defect in said electrical circuit pattern in the course of said initial inspection, interrupting said initial inspection and carrying out a secondary evaluation of a portion of said sequentially acquired image including said potential defect; and
following completion of said secondary inspection, resuming said initial inspection.

2. The method according to claim 1 and wherein said sequentially acquired image is acquired by continuously scanning an electrical circuit pattern to be inspected.

3. The method according to claim 1 and wherein said sequentially acquired image is acquired by sequentially imaging two dimensional regions of said electrical circuit pattern.

4. The method according to claim 1 and wherein said carrying out an initial inspection comprises inspecting said sequentially acquired image at an inspection rate faster than a rate at which said sequentially acquired image is acquired.

5. The method according to claim 1 and further comprising buffering portions of said sequentially acquired image as they are being acquired while carrying out said secondary evaluation.

6. The method according to claim 4 and further comprising buffering portions of said sequentially acquired image as they are being acquired while carrying out said secondary evaluation.

7. The method according to claim 6 and wherein said resuming said initial inspection comprises inspecting buffered portions at a rate that is faster than said inspection rate and then further inspecting additional sequentially acquired portions of said image at said inspection rate.

8. The method according to claim 1 and wherein said carrying out an initial inspection of a sequentially acquired image comprises inspecting a contour representation of said electrical circuit pattern.

9. The method according to claim 1 and wherein carrying out a second evaluation comprises an algorithm set that is different from the algorithm set of said initial inspection.

10. The method according to claim 9. and wherein said carrying out a second evaluation comprises an algorithm set that requires more computer resources than said initial inspection.

11. A method for inspecting electrical circuit patterns comprising:
acquiring an image of an electrical circuit pattern during an image acquisition time interval;
carrying out an initial inspection of said image at a rate which is faster than a rate at which said images are acquired; and
in response to said initial inspection, carrying out an additional evaluation of portions of said image, wherein a time interval for carrying out said initial inspection and said additional evaluation is substantially the same as said image acquisition time interval.

12. The method for inspecting electrical circuits claimed in claim 11 and wherein said initial inspection and said additional evaluation are both performed using the same computer processor.

13. The method for inspecting electrical circuits claimed in claim 11 and wherein said carrying out an initial inspection employs a first algorithm set and said carrying out an additional evaluation comprises using a second algorithm set different from said first algorithm set.

14. The method for inspecting electrical circuits claimed in claim 13 and wherein said second algorithm set uses more computer resources than said first algorithm set.

15. The method for inspecting electrical circuits claimed in claim 13 and wherein said second algorithm set requires a longer time interval to inspect a given portion of said image than said first algorithm set.

16. The method for inspecting electrical circuits claimed in claim 12 and wherein said initial inspection is interrupted in response to identifying a potential defect on said electrical circuit pattern, and said additional evaluation is performed on an image portion whereat said potential defect is identified.

17. The method according to claim 11 and wherein said acquiring an image comprises acquiring a contour representation of said electrical circuit pattern.

18. A method for inspecting electrical circuit patterns comprising:
acquiring an image of said electrical circuit pattern to be inspected;
identifying portions of said image that are different from a corresponding reference portion by difference greater than a first difference threshold;
micro-registering said portions; and
evaluating a micro-registered portion to determine a defect in said electrical circuit pattern.

19. The method according to claim 18 and wherein said acquiring an image comprises acquiring a contour representation including contours of said electrical circuit to be inspected.

20. The method according to claim 19 and wherein said identifying comprises extracting a segment of a contour whose difference from a corresponding reference is greater than said first difference threshold.

21. The method according to claim 18 and wherein said micro-registering comprises aligning a portion that is different from a corresponding reference portion and said corresponding reference portion in an iterative process.

22. The method according to claim 18 and wherein said micro-registering comprises aligning a portion that is different from a corresponding reference portion and said corresponding reference portion with reference to a collection of alignment points.

23. The method according to claim 22 and wherein said alignment points are associated with a vector indicative of a side of a contour which is a conductor and side of said contour which is a substrate.

24. The method according to claim 23 and wherein said vector is employed to determine a corresponding location in said image.

25. The method according to claim 18 and wherein said identifying portions employs a first algorithm set and said evaluating employs a second algorithm set.

26. The method according to claim 25 and wherein said second algorithm set requires more computer resources than said first algorithm set.

27. The method according to claim 18 and wherein said identifying portions is performed with reference to a first threshold.

28. The method according to claim 27 and wherein said evaluating is performed with reference to a second threshold or with reference to an distance by which a portion is micro-registered.

29. A method for inspecting electrical circuits comprising:
forming a contour representation of an electrical circuit to be inspected;
initially inspecting a multiplicity of locations on said contour representation in order to locate a first plurality of locations, among said multiplicity of locations, having a first possibility of defects; and
during said initially inspecting, upon identifying said first plurality of locations carrying out a second stage inspection of said first plurality of locations in order to determine which of said first plurality of locations constitutes a second plurality of locations having a second possibility of defects, greater than said first possibility of defects.

30. A method for pattern inspection comprising the steps of:
comparing pattern characteristic descriptors in a pattern to be inspected and in a reference and providing a comparison output;
applying a relatively high quality threshold to said comparison output to provide a threshold output which distinguishes between pattern portions which meet said relatively high quality threshold and pattern portions which do not meet said relatively high quality threshold; and
thereafter, further inspecting the pattern portions which do not meet said relatively high quality threshold.

31. A method for inspecting a pattern for defects comprising:
representing as a first polygon at least two predetermined characteristics of a portion of a pattern to be inspected;
representing as a second polygon at least two predetermined characteristics of a reference portion corresponding to said portion of a pattern to be inspected; and
making a defect determination in said portion of a pattern to be inspected by comparing said first polygon to said second polygon.

32. The method claimed in claim 31 and wherein said predetermined characteristics comprise statistical moments associated with a spatial distribution of locations in a portion of a pattern to be inspected or in a reference portion.

33. A method for pattern inspection comprising comparing a pattern to be inspected and a reference by:
representing a collection of spatial characteristics of a portion of said pattern to be inspected as a first polygon;
representing a collection of spatial characteristics of a portion of a reference corresponding to said pattern to be inspected as a second polygon;
comparing said first polygon and said second polygon to determine defects in said pattern.

34. The method claimed in claim 33 and wherein said first polygon and said second polygon represent a distribution of said spatial characteristics.

35. The method claims in claim 34 and wherein said spatial characteristics comprise statistical moments.

36. A method for pattern inspection comprising:
providing a representation of a pattern to be inspected substantially without identifying functional structures making up the pattern;
comparing said representation to a corresponding reference and outputting and extracting portions of said representation that are different from said reference by a difference that is greater than a predetermined permissible difference threshold; and
locally processing at least some extracted portions to identify defects in said pattern.

37. The method claimed in claim 36 and wherein said providing said representation comprises providing a representations of contours in said pattern.

38. A method for pattern inspection comprising the steps of:
comparing pattern characteristic descriptors in a pattern to be inspected and in a reference and providing a comparison output;
applying a relatively high quality threshold to said comparison output to provide a threshold output which distinguishes between pattern portions which meet said relatively high quality threshold and pattern portions which do not meet said relatively high quality threshold; and
further inspecting the pattern portions which do not meet said relatively high quality threshold.

39. A method for pattern inspection according to claim 38 and wherein at least one of said descriptors comprises a contour of at least a portion of a pattern.

40. A method for pattern inspection according to claim 38 and wherein at least one of said descriptors comprises an edge of at least a portion of a pattern.

41. A method for pattern inspection according to claim 38 and wherein at least one of said descriptors comprises a color of at least a portion of a pattern.

42. A method for pattern inspection according to claim 38 and wherein at least one of said descriptors comprises a geometrical characteristic of at least a portion of a pattern.

43. A method for pattern inspection according to claim 42 and wherein said pattern comprises a conductive pattern formed on a printed circuit board.

44. A method for pattern inspection according to claim 38 and wherein the number of pattern portions which meet said relatively high quality threshold normally substantially exceeds the number of pattern portions which do not meet said relatively high quality threshold.

45. A method for pattern inspection according to claim 38 and wherein said comparing the pattern to be inspected and the reference and providing a comparison output and applying a relatively high quality threshold to said comparison output to provide a threshold output which distinguishes between pattern portions which meet said relatively high quality threshold and pattern portions which do not meet said relatively high quality threshold are normally carried out using less computational resources per pattern portion inspected than said step of further inspecting.

46. A method for pattern inspection according to claim 44 and wherein said steps of comparing the pattern to be inspected and the reference and providing a comparison output and applying a relatively high quality threshold to said comparison output to provide a threshold output which distinguishes between pattern portions which meet said relatively high quality threshold and pattern portions which do not meet said relatively high quality threshold are normally carried out using less computational resources per pattern portion inspected than said step of further inspecting.

47. A method for pattern inspection according to claim 38 and wherein said further inspecting employs at least one second threshold which is less stringent than said relatively high quality threshold.

48. A method according to claim 38 and wherein said step of comparing comprises a contour element-to-contour element comparison.

49. A method according to claim 38 and wherein said step of comparing comprises a pixel-to-pixel comparison.

50. A method for fabricating electrical circuits, comprising:
depositing a portion of an electrical circuit on a substrate according to a pattern;
carrying out an initial inspection of a sequentially acquired image of said pattern to determine potential defects in said portion of an electrical circuit;
upon identifying a potential defect in said pattern in the course of said initial inspection, interrupting said initial inspection and carrying out a secondary evaluation of a portion of said sequentially acquired image including said potential defect; and
following completion of said secondary inspection, resuming said initial inspection.

51. A method for fabricating electrical circuits, comprising:
depositing a portion of an electrical circuit on a substrate according to a pattern;
acquiring an image of said electrical circuit during an image acquisition time interval;
carrying out an initial inspection of said image at a rate which is faster than a rate at which said images are acquired; and
in response to said initial inspection, carrying out an additional evaluation of portions of said image, wherein a time interval for carrying out said initial inspection and said additional evaluation is substantially the same as said image acquisition time interval.

52. A method for fabricating electrical circuits, comprising:
depositing a portion of an electrical circuit on a substrate according to a pattern;
acquiring an image of said electrical circuit to be inspected;
identifying portions of said image that are different from a corresponding reference portion by difference greater than a first difference threshold;
micro-registering said portions; and
evaluating a micro-registered portion to determine a defect in the electrical circuit pattern.

53. A method for fabricating electrical circuits, comprising:
depositing a portion of an electrical circuit on a substrate according to a pattern;
forming a contour representation of said pattern of an electrical circuit to be inspected;
initially inspecting a multiplicity of locations on said contour representation in order to locate a first plurality of locations, among said multiplicity of locations, having a first possibility of defects; and
during said initially inspecting, upon identifying said first plurality of locations carrying out a second stage inspection of said first plurality of locations in order to determine which of said first plurality of locations constitutes a second plurality of locations having a second possibility of defects, greater than said first possibility of defects.

54. A method for fabricating an electrical circuit, comprising:
depositing a portion of an electrical circuit on a substrate according to a pattern;
providing a representation of an electrical circuit portion to be inspected substantially without identifying functional structures making up the electrical circuit;
comparing said representation to a corresponding reference and extracting portions of said representation that are different from said reference by a difference that is greater than a predetermined permissible difference threshold; and
locally processing at least some extracted portions to identify defects in said electrical circuit.

55. A method for fabricating electrical circuits, comprising:
depositing a portion of an electrical circuit on a substrate according to a pattern;
comparing pattern characteristic descriptors in an electrical circuit to be inspected and in a reference and providing a comparison output;
applying a relatively high quality threshold to said comparison output to provide a threshold output which distinguishes between pattern portions which meet said relatively high quality threshold and pattern portions which do not meet said relatively high quality threshold; and
further inspecting the pattern portions which do not meet said relatively high quality threshold.
